(19) United States
(12) Patent Application Publication
(10) Pub. No.: US 2026/0173614 A1
(43) Pub. Date: Jun. 18, 2026

(54) DISPLAY SUBSTRATE, MANUFACTURING METHOD THEREOF, AND DISPLAY APPARATUS

(71) Applicants: Beijing BOE Technology Development Co., Ltd., Beijing (CN); BOE Technology Group Co., Ltd., Beijing (CN)

(72) Inventors: Shulei LI, Beijing (CN); Changhan HSIEH, Beijing (CN); Jinqian WANG, Beijing (CN); Yuanyuan MA, Beijing (CN); Miaomiao JIA, Beijing (CN); Zhao KANG, Beijing (CN); Hua HUANG, Beijing (CN); Mingyang TIAN, Beijing (CN); Feng WANG, Beijing (CN); Xueyong WANG, Beijing (CN)

(21) Appl. No.: 18/851,781

(22) PCT Filed: Sep. 27, 2023
(86) PCT No.: PCT/CN2023/122190

§ 371 Date: Sep. 27, 2024

(51) Int. Cl. H10H 29/49; H10H 29/01; H10H 29/852

(52) U.S. Cl. CPC H10H 29/49; H10H 29/012; H10H 29/852

(57) ABSTRACT

A display substrate includes: a base substrate; a driver circuit layer on the base substrate; a plurality of transfer electrodes on a side of the driver circuit layer away from the base substrate and electrically connected to the driver circuit layer; a plurality of light-emitting chips on a side of the plurality of transfer electrodes away from the base substrate, where each light-emitting chip includes a first electrode and a light-emitting body layer sequentially arranged in a direction away from the base substrate, and each first electrode is bonded to one of the transfer electrodes; a first voltage line including a first conductive layer and a second conductive layer, where the first conductive layer is in the same layer as the transfer electrodes, and the second conductive layer is in the same layer as the first electrode; and the first conductive layer is bonded to the second conductive layer.

### TECHNICAL FIELD

The present disclosure relates to the field of display technology, and specifically relates to a display substrate, a manufacturing method thereof, and a display apparatus.

### BACKGROUND

Micro inorganic light-emitting diodes include MiniLEDs and MicroLEDs. The MiniLED refers to a light-emitting diode (LED) chip with a grain size of about 100 to 300 microns. The MicroLED refers to an LED chip with a grain size of less than 100 microns. The MiniLED/MicroLED display apparatus has the advantages of low power consumption, high brightness, high resolution, high color saturation, fast response, long service life, high efficiency and the like. In addition, a plurality of Mini-LED/Micro-LED display devices may be seamlessly spliced to obtain an oversized display product, which has promising application prospects in large-size display fields including command and monitoring centers, business centers, high-end conferences, cinemas and the like.

### SUMMARY

In a first aspect, the present disclosure provides a display substrate, including:
a base substrate;
a driver circuit layer on the base substrate;
a plurality of transfer electrodes on a side of the driver circuit layer away from the base substrate and electrically connected to the driver circuit layer;
a plurality of light-emitting chips on a side of the plurality of transfer electrodes away from the base substrate, wherein each light-emitting chip includes a first electrode and a light-emitting body layer sequentially arranged in a direction away from the base substrate, and each first electrode is bonded to one of the transfer electrodes; and
a first voltage line including a first conductive layer and a second conductive layer, wherein the first conductive layer is in the same layer as the transfer electrodes, and the second conductive layer is in the same layer as the first electrode; and the first conductive layer is bonded to the second conductive layer.

In some embodiments, orthographic projections of the first electrode and the transfer electrode connected to the first electrode on the base substrate coincide with each other; and orthographic projections of the first conductive layer and the second conductive layer on the base substrate coincide with each other.

In some embodiments, the driver circuit layer includes a plurality of thin film transistors electrically connected to the transfer electrodes;
the first voltage line further includes: a third conductive layer in the same layer as sources and drains of the thin film transistors, and the first conductive layer is electrically connected to the third conductive layer.

In some embodiments, each transfer electrode includes, sequentially in the direction away from the base substrate: a reflective layer and a bonding layer; and the first conductive layer includes: a first conductive sublayer and a second conductive sublayer, wherein the first conductive sublayer is in the same layer as the reflective layer, and the second conductive sublayer is in the same layer as the bonding layer.

In some embodiments, the display substrate further includes a planarization layer between the driver circuit layer and the plurality of transfer electrodes, and the transfer electrodes are electrically connected to the driver circuit layer through first vias running through the planarization layer.

In some embodiments, the light-emitting chip further includes a second electrode on a side of the light-emitting body layer away from the base substrate; and the first voltage line further includes a fourth conductive layer electrically connected to the second conductive layer, wherein the fourth conductive layer is in the same layer as, and electrically connected to, the second electrode.

In some embodiments, the display substrate further includes:
an encapsulation layer on a side of the driver circuit layer away from the base substrate; and the encapsulation layer has a plurality of first receiving parts, each of which receives the first electrode and the light-emitting body layer of one of the light-emitting chips;
wherein the fourth conductive layer is electrically connected to the second conductive layer through a second via running through the encapsulation layer.

In some embodiments, each light-emitting chip is configured to emit first color light; and the display substrate further includes:
a light-shielding layer having a plurality of second receiving parts, each of which exposes at least partially one of the second electrodes;
a plurality of light-outgoing parts, each of which is in one of the second receiving parts and on a side of the second electrode away from the base substrate; wherein the plurality of light-outgoing parts include: a plurality of first light-outgoing parts, a plurality of second light-outgoing parts, and a plurality of third light-outgoing parts, wherein the first light-outgoing parts transmit the first color light emitted by the light-emitting chips; the second light-outgoing parts are configured to convert the first color light into second color light; and the third light-outgoing parts are configured to convert the first color light into third color light; and
a plurality of color filter blocks, each of which is on a side of one of the light-outgoing parts away from the base substrate and has a color the same as the light emitted from a corresponding light-outgoing part.

In some embodiments, the light-emitting chips are mini-LED light-emitting chips or Micro-LED light-emitting chips.

In a second aspect, the present disclosure provides a method for manufacturing a display substrate, including:
forming a driver circuit layer on a base substrate;
forming a first bonding layer on a side of the driver circuit layer away from the base substrate;
providing an epitaxial wafer including a second bonding layer and an epitaxial layer in a stack;
transferring the epitaxial wafer to a side of the first bonding layer away from the base substrate, and bonding the first bonding layer to the second bonding layer;
etching the epitaxial layer to form a first pattern; etching the second bonding layer to form a second pattern; and etching the first bonding layer to form a third pattern; and
wherein the first pattern includes light-emitting body layers of a plurality of light-emitting chips, the second pattern includes first electrodes of the plurality of light-emitting chips and a second conductive layer of a first voltage line, and the third pattern includes a plurality of transfer electrodes, and a first conductive layer of the first voltage line; and the transfer electrodes are electrically connected to the driver circuit layer.

In some embodiments, etching the second bonding layer and etching the first bonding layer are performed in a same patterning process.

In some embodiments, forming the driver circuit layer on the base substrate includes: forming a plurality of thin film transistors on the base substrate, wherein the transfer electrodes are electrically connected to the thin film transistors;
wherein a third conductive layer of the first voltage line is formed while forming sources and drains of the plurality of thin film transistors; and the first conductive layer is electrically connected to the third conductive layer.

In some embodiments, the first bonding layer includes a reflective material layer and a bonding material layer sequentially arranged in a direction away from the base substrate;
each transfer electrode includes: a reflective layer and a bonding layer; and the first conductive layer includes: a first conductive sublayer and a second conductive sublayer;
wherein the first conductive sublayer and the reflective layer are formed by etching the reflective material layer, and the second conductive sublayer and the bonding layer are formed by etching the bonding material layer.

In some embodiments, before forming the first bonding layer, the method further includes:
forming a planarization layer on a side of the driver circuit layer away from the base substrate; and
forming first vias in the planarization layer at positions corresponding to the transfer electrodes;
wherein the transfer electrodes are electrically connected to the driver circuit layer through the first vias, respectively.

In some embodiments, the method further includes:
forming second electrodes of the plurality of light-emitting chips and a plurality of fourth conductive layers of the first voltage line synchronously;
wherein the fourth conductive layers are electrically connected to the second conductive layer and the second electrode, and the second electrode is on a side of the light-emitting body layer away from the base substrate.

In some embodiments, before forming the second electrodes of the plurality of light-emitting chips synchronously, the method further includes:
forming an encapsulation layer having a plurality of first receiving parts and a plurality of second vias;
wherein the first electrode and the light-emitting body layer of each light-emitting chip are in one of the first receiving parts, and the fourth conductive layers are electrically connected to the second conductive layer through the second vias.

In some embodiments, each light-emitting chip is configured to emit first color light; and the method further includes:
forming a light-shielding layer having a plurality of second receiving parts;
forming a light-outgoing part in each of the second receiving parts, wherein the light-outgoing part is on a side of the second electrodes away from the base substrate; light-outgoing parts in the plurality of second receiving parts include: a first light-outgoing part, a second light-outgoing part, and a third light-outgoing part, wherein the first light-outgoing part transmits the first color light emitted by the light-emitting chips, the second light-outgoing part is configured to convert the first color light into second color light; and the third light-outgoing part is configured to convert the first color light into third color light; and
forming a color filter block on a side of each light-outgoing part away from the base substrate, and wherein the color filter block has a color the same as the light emitted from a corresponding light-outgoing part.

In a third aspect, the present disclosure provides a display apparatus, including the display substrate in any of the above embodiments.

### BRIEF DESCRIPTION OF DRAWINGS

Accompanying drawings are provided for further understanding of the present disclosure and constitute a part of the specification. Hereinafter, these drawings are intended to explain the present disclosure together with the following specific implementations, but should not be considered as a limitation on the present disclosure. In the drawings:

FIG. 1 is a schematic diagram of a display substrate according to some embodiments of the present disclosure.

FIG. 2 is a schematic diagram of a display substrate according to some other embodiments of the present disclosure.

FIG. 3 is a schematic diagram of a display substrate according to some other embodiments of the present disclosure.

FIGS. 4 to 18 are schematic diagrams illustrating a manufacturing process of a display substrate according to some embodiments of the present disclosure.

### DETAIL DESCRIPTION OF EMBODIMENTS

Hereinafter, specific implementations of the present disclosure will be described with respect to the accompanying drawings. It will be appreciated that the specific implementations as set forth herein are merely for the purpose of illustration and explanation of the present disclosure and should not be constructed as a limitation thereon.

To make the objects, technical solutions and advantages of the embodiments of the present disclosure more apparent, the technical solutions according to the embodiments of the present disclosure will be clearly and completely described below with reference to the drawings of the embodiments of the present disclosure. Apparently, the described embodiments are some, but not all, of the embodiments of the present disclosure. All other embodiments obtained by those of ordinary skill in the art based on the embodiments of the present disclosure described herein without paying any creative effort shall be included in the protection scope of the present disclosure.

Unless otherwise defined, technical or scientific terms used in the embodiments of the present disclosure are intended to have general meanings as understood by those of ordinary skill in the art to which the present disclosure belongs. The words “first”, “second” and similar terms used in the present disclosure do not denote any order, quantity, or importance, but are used merely for distinguishing different components from each other. Likewise, the word “comprising” or “including” or the like means that the element or item preceding the word contains elements or items that appear after the word or equivalents thereof, but does not exclude other elements or items. The terms “connected” or “coupled” and the like are not restricted to physical or mechanical connections, but may include electrical connections, whether direct or indirect. The words “upper”, “lower”, “left”, “right”, and the like are merely used to indicate a relative positional relationship, and when an absolute position of the described object is changed, the relative positional relationship may be changed accordingly.

As used herein, “parallel” or “perpendicular” includes the recited case and cases that approximate the recited case to within an acceptable range of deviation as determined by those of ordinary skill in the art in view of the measurement in question and the error associated with the measurement of the particular quantity (i.e., the limitations of the measurement system). For example, “parallel” includes “absolutely parallel” and “approximately parallel”, where an acceptable deviation of “approximately parallel” may be, for example, within 5°; and “perpendicular” includes “absolutely perpendicular” and “approximately perpendicular”, where an acceptable deviation of “approximately perpendicular” may also be, for example, within 5°.

It will be understood that when a layer or element is referred to as being “on” another layer or substrate, the layer or element may be directly on the another layer or substrate, or an intervening layer may be present between the layer or element and the another layer or substrate.

Exemplary implementations are described herein with reference to sectional and/or plan views as idealized exemplary figures. In the drawings, the thicknesses of layers and regions are exaggerated for clarity. Variations from the shapes in the figures as a result of, for example, manufacturing techniques and/or tolerances, are to be expected. Therefore, exemplary implementations should not be construed as limited to the shapes of regions illustrated herein, but are to include deviations in shapes that result, for example, from manufacturing. Therefore, the regions illustrated in the figures are schematic in nature, and their shapes are not intended to illustrate the actual shape of a region of a device, or intended to limit the scope of exemplary implementations.

In the existing art, for a display panel using a MiniLED or a MicroLED light-emitting chip, the manufacturing process includes: providing a plurality of light-emitting chips in a display region of a driving backplane through mass transfer and mass bonding processes. The driving backplane includes a base substrate, and a driver circuit layer on the base substrate, and the driver circuit layer is electrically connected to a first electrode of each light-emitting chip to provide a driving signal for the light-emitting chip. In addition, the driving backplane further includes a first voltage line electrically connected to the second electrode of the light-emitting chip and configured to provide a first voltage signal to the second electrode.

However, due to the high price of the MiniLED and MicroLED light-emitting chips, the cost of a display panel using the MiniLED or MicroLED light-emitting chips is relatively high. Moreover, the mass transfer and mass bonding processes are relatively difficult.

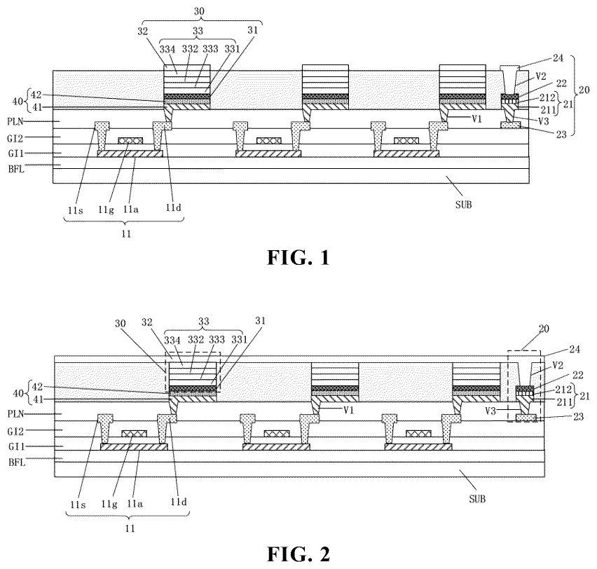

FIG. 1 is a schematic diagram of a display substrate according to some embodiments of the present disclosure, FIG. 2 is a schematic diagram of a display substrate according to some other embodiments of the present disclosure, and FIG. 3 is a schematic diagram of a display substrate according to some other embodiments of the present disclosure. As shown in FIGS. 1 to 3, the display substrate includes a base substrate SUB, a driver circuit layer on the base substrate SUB, a first voltage line 20, a plurality of transfer electrode 40, and a plurality of light-emitting chips 30.

The base substrate SUB may be a rigid substrate made of an inorganic material. For example, the base substrate SUB may be made of soda-lime glass, quartz glass, sapphire glass, or any other glass material. Alternatively, the base substrate SUB may be a flexible substrate made of an organic material. For example, the base substrate SUB may be made of polymethyl methacrylate (PMMA), polyvinyl alcohol (PVA), polyimide (PI), polycarbonate (PC), polyethylene terephthalate (PET), polyethylene naphthalate (PEN), or a combination thereof.

The driver circuit layer is configured to provide a driving signal for each light-emitting chip 30.

A plurality of transfer electrodes 40 are provided on a side of the driver circuit layer away from the base substrate SUB. The transfer electrode 40 may include a first material.

The plurality of light-emitting chips 30 are provided in a display region of the display substrate, and each light-emitting chip 30 includes a first electrode 31 and a light-emitting body layer 33 sequentially arranged in a direction away from the base substrate SUB, where each first electrode 31 corresponds to one of the transfer electrodes 40. For example, the first electrodes 31 are in one-to-one correspondence with the transfer electrodes 40. Each first electrode 31 is electrically connected to the driver circuit layer through a corresponding transfer electrode 40. The first electrode 31 includes a second material.

The first voltage line 20 includes a first conductive layer 21 and a second conductive layer 22 sequentially arranged in a direction away from the base substrate SUB. The first conductive layer 21 is disposed in the same layer as the transfer electrodes 40, and the second conductive layer 22 is disposed in the same layer as the first electrodes 31.

It should be noted that when referring to “disposed in the same layer” in the embodiments of the present disclosure, it means that two structures are formed by the same material layer through a patterning process, and therefore, the two structures are located in the same layer in terms of the hierarchical relationship; but it does not necessarily mean that the two structures have the same distance to the base substrate SUB.

Each first electrode 31 is bonded to a corresponding transfer electrode 40, and the first conductive layer 21 is bonded to the second conductive layer 22.

Optionally, the first electrode 31 and the transfer electrode 40, as well as the first conductive layer 21 and the second conductive layer 22, are bonded by eutectic bonding, so as to improve the bonding strength. In other words, a eutectic metal layer formed by the first material reacted with the second material is formed between the first electrode 31 and the transfer electrode 40, and between the first conductive layer 21 and the second conductive layer 22, respectively.

In an embodiment of the present disclosure, a combination of the first material and the second material may be selected as any one of: copper (Cu) and tin (Sn); copper (Cu) and indium (In); gold (Au) and indium (In); gold (Au) and tin (Sn); or indium tin oxide (ITO) and indium tin oxide (ITO).

In an embodiment of the present disclosure, the first conductive layer 21 is disposed in the same layer as the transfer electrodes 40, the second conductive layer 22 is disposed in the same layer as the first electrodes 31, the first electrodes 31 are bonded to the transfer electrodes 40, and the first conductive layer 21 is bonded to the second conductive layer 22. Therefore, in the manufacturing process of the display substrate, a first bonding layer may be formed on the base substrate SUB on which the driver circuit layer is formed, then an epitaxial wafer including a second bonding layer and an epitaxial layer is integrally transferred to the base substrate SUB, and the first bonding layer is bonded to the second bonding layer, so that a eutectic metal layer is formed between the first bonding layer and the second bonding layer; then, the epitaxial layer is etched to form a pattern including a plurality of light-emitting body layers 33; the second bonding layer is etched to form a pattern including a plurality of second conductive layers 22 and a plurality of first electrodes 31; and the first bonding layer is etched to form a pattern including a plurality of first conductive layers 21 and a plurality of transfer electrodes 40. In this manner, there is no need to transfer or bond a large number of light-emitting chips 30 through mass transfer and mass bonding processes, as along as the whole epitaxial wafer is transferred, bonded and patterned, thereby reducing the process difficulty. Moreover, the price of a single epitaxial wafer is much lower than a large number of light-emitting chips 30, thereby reducing the production cost of the display substrate.

In some embodiments, as shown in FIGS. 1 to 3, orthographic projections of the first electrode 31 and the transfer electrode 40 connected to the first electrode 31 on the base substrate SUB coincide with each other; and orthographic projections of the first conductive layer 21 and the second conductive layer 22 on the base substrate SUB coincide with each other.

When the light-emitting chips are transferred to the driver circuit layer through a mass transfer process, the electrodes above the driver circuit layer for connecting the light-emitting chips are typically designed to be larger to ensure accurate alignment. In the embodiments of the present disclosure, however, in the manufacturing process of the display substrate, the second bonding layer and the first bonding layer may be etched by the same patterning process to form the first electrode 31 and the transfer electrode 40 with coincided orthogonal projections, and the second conductive layer 22 and the first conductive layer 21 with coincided orthogonal projections, so that the manufacturing process can be simplified while stable connection of the first electrodes 31 and the transfer electrodes 40 is ensured.

In some embodiments, as shown in FIGS. 1 to 3, orthographic projections of the first electrode 31 and the light-emitting body layer 33 on the base substrate SUB coincide with each other. Apparently, the orthographic projections of the first electrode 31 and the light-emitting body layer 33 on the base substrate SUB may not completely coincide with each other.

In some embodiments, as shown in FIGS. 1 to 3, a buffer layer BFL is provided on the base substrate SUB, which can prevent or reduce diffusion of metal atoms and/or impurities from the base substrate SUB into the semiconductor layer. For example, the buffer layer BFL may include an inorganic material such as SiOx, SiNx, and/or SiON, and may be formed as a multi-layer or single-layer structure.

As shown in FIGS. 1 to 3, the driver circuit layer is disposed on a side of the buffer layer BFL away from the base substrate SUB, and the driver circuit layer may include pixel driver circuits in one to one correspondence with the light-emitting chips 30. Each pixel driver circuit includes a plurality of thin film transistors 11. Only one thin film transistor 11 in the pixel driver circuit is schematically labeled in FIG. 1. The thin film transistor 11 may be a top gate thin film transistor or a bottom gate thin film transistor, and the top gate thin film transistor is taken as an example for description in the embodiments of the present disclosure.

As shown in FIGS. 1 to 3, a semiconductor layer is disposed on a side of the buffer layer BFL away from the base substrate SUB. The semiconductor layer may include, for example, an inorganic semiconductor material (e.g., polysilicon, amorphous silicon, etc.), an organic semiconductor material, or an oxide semiconductor material. The semiconductor layer may include active layers 11a of the plurality of thin film transistors 11, and each active layer 11a may include a channel region overlapped with a gate 11g, and a source region and a drain region on two sides of the channel region, respectively. The source region and the drain region may each have a higher concentration of impurities than the channel region. The impurities may include N-type impurities or P-type impurities.

As shown in FIGS. 1 to 3, a first gate insulator layer GI1 is disposed on a side of the semiconductor layer away from the base substrate SUB. The first gate insulator layer GII may include, for example, a silicon compound or a metal oxide. For example, the first gate insulator layer GI1 may include, silicon oxynitride (SiON), silicon oxide (SiOx), silicon nitride (SiNx), silicon oxycarbide (SiOxCy), silicon carbonitride (SiCxNy), aluminum oxide (AlOx), aluminum nitride (AlNx), tantalum oxide (TaOx), hafnium oxide (HfOx), zirconium oxide (ZrOx), titanium oxide (TiOx), or the like. The first gate insulator layer GII may be formed as a single-layer or multi-layer structure.

As shown in FIGS. 1 to 3, gates 11g of the plurality of thin film transistors 11 are disposed on a side of the first gate insulator layer GII away from the base substrate SUB. The gate 11g may include, for example, a metal, a metal alloy, a metal nitride, a conductive metal oxide, a transparent conductive material, and the like. For example, the gate 11g may include gold (Au), an alloy of gold, silver (Ag), an alloy of silver, aluminum (Al), an alloy of aluminum, aluminum nitride (AlNx), tungsten (W), tungsten nitride (WNx), copper (Cu), an alloy of copper, nickel (Ni), chromium (Cr), chromium nitride (CrNx), molybdenum (Mo), an alloy of molybdenum, titanium (Ti), titanium nitride (TiNx), platinum (Pt), tantalum (Ta), tantalum nitride (TaNx), neodymium (Nd), scandium (Sc), strontium ruthenium oxide (SRO), zinc oxide (ZnOx), tin oxide (SnOx), indium oxide (InOx), gallium oxide (GaOx), indium tin oxide (ITO), indium zinc oxide (IZO), or the like. The gate 11g may have a single-layer or multi-layer structure.

As shown in FIGS. 1 to 3, a second gate insulator layer GI2 may include, silicon oxynitride (SiON), silicon oxide (SiOx), silicon nitride (SiNx), silicon oxycarbide (SiOxCy), silicon carbonitride (SiCxNy), aluminum oxide (AlOx), aluminum nitride (AlNx), tantalum oxide (TaOx), hafnium oxide (HfOx), zirconium oxide (ZrOx), titanium oxide (TiOx), or the like. The second gate insulator layer GI2 may be formed as a single-layer or multi-layer structure.

A source-drain conductive layer is disposed on a side of the second gate insulator layer GI2 away from the base substrate SUB. The first voltage line 20 includes a third conductive layer 23, which is disposed in the same layer as a source 11s and a drain 11d of the thin film transistor 11 and located in the source-drain conductive layer. The source 11s of the thin film transistor 11 is electrically connected to the source region, while the drain 11d is electrically connected to the drain region. In an embodiment of the present disclosure, the source-drain conductive layer may include a metal, an alloy, a metal nitride, a conductive metal oxide, a transparent conductive material, or the like. For example, the source-drain conductive layer may be a single-layer or multi-layer structure made of a metal, such as Mo/Al/Mo or Ti/Al/Ti.

As shown in FIGS. 1 to 3, a planarization layer PLN is disposed on a side of the driver circuit layer away from the base substrate SUB, and the planarization layer PLN may include an organic insulating material including, for example, a resin-based material such as polyimide, epoxy, acryl, polyester, photoresist, polyacrylate, polyamide, siloxane, or the like.

The planarization layer PLN may have a thickness between 2 μm and 5 μm, such as 2 μm, 3 μm, 4 μm, or 5 μm, which is beneficial to improve the surface flatness of the planarization layer PLN. In one example, the flatness (i.e., a height difference between the highest point and the lowest point) of a surface of the planarization layer PLN away from the base substrate base SUB is less than 100 nm.

As shown in FIGS. 1 to 3, the plurality of transfer electrodes 40 and the first conductive layer 21 of the first voltage line are located on a side of the planarization layer PLN away from the base substrate SUB. Each transfer electrode 40 is electrically connected to the thin film transistor 11 in the driver circuit layer through a first via V1 running through the planarization layer PLN. Each transfer electrode 40 may be connected to one thin film transistor 11. The first conductive layer 21 is electrically connected to the corresponding third conductive layer 23 through a third via V3 running through the planarization layer PLN.

As shown in FIGS. 1 to 3, the transfer electrode 40 includes, sequentially in a direction away from the base substrate SUB: a reflective layer 41 and a bonding layer 42. Orthographic projections of the reflective layer 41 and the bonding layer 42 on the base substrate SUB may coincide with each other. A material of the bonding layer 42 may include the first material described above.

The reflective layer 41 may be made of a material including at least one of silver (Ag), aluminum (Al), molybdenum (Mo), titanium (Ti) or chromium (Cr). For example, the reflective layer 41 may be made of silver (Ag) which has good reflective properties, and may have a thickness between 10 nm and 200 nm. With such a reflective layer 41, the emission efficiency of the top-emission light-emitting chip 30 can be increased.

The first conductive layer 21 includes: a first conductive sublayer 211 and a second conductive sublayer 212. The first conductive sublayer 211 is disposed in the same layer as the reflective layer 41, and the second conductive sublayer 212 is disposed in the same layer as the bonding layer 42.

A plurality of light-emitting chips 30 are disposed on a side of the plurality of transfer electrodes 40 away from the base substrate SUB 30. The light-emitting chips 30 may be mini-LED light-emitting chips 30 or Micro-LED light-emitting chips 30. First electrodes 31 of the light-emitting chips 30 are bonded to the transfer electrodes 40 in one-to-one correspondence. An IMC (Intermetallic Compound) eutectic metal layer is formed between each first electrode 31 and the corresponding transfer electrode 40, and the eutectic metal layer is formed by the first material of the bonding layer 42 reacted with the second material of the first electrode 31. The second conductive layer 22 is disposed in the same layer as the first electrodes 31 and bonded to the first conductive layer 21, so that a eutectic metal layer is formed between the first conductive layer 21 and the second conductive layer 22.

In an embodiment of the present disclosure, since the planarization layer PLN is disposed on the side of the driver circuit layer away from the base substrate SUB, the transfer electrode 40 can be located on a substantially flat surface, and the bonding effect between the transfer electrode 40 and the first electrode 31 is further improved.

As shown in FIGS. 1 to 3, a light-emitting body layer 33 is located on a side of the first electrode 31 away from the base substrate SUB, and the light-emitting body layer 33 may include a first semiconductor layer 331, an active layer 333, a second semiconductor layer 332, and a buffer layer 334 sequentially arranged in a direction away from the base substrate SUB. The buffer layer 334 may include GaN, AlN, AlGaN, or InGaN.

The first semiconductor layer 331 may be an n-type nitride semiconductor layer including a composition of InₓAl_{y}Ga_{1-x-y}N (0≤x<1, 0≤y<1, and 0≤x+y<1), where the n-type impurity may be silicon. For example, the first semiconductor layer 331 may include n-type GaN. The second semiconductor layer 332 may be a p-type nitride semiconductor layer including a composition of InₓAl_{y}Ga_{1-x-y}N (0≤x<1, 0≤y<1, and 0≤x+y<1), where the p-type impurity may be magnesium. For example, the second semiconductor layer 332 may have a single-layer structure, but may have a multi-layer structure of different compositions in some exemplary embodiments. The active layer 333 may have a multiple quantum well (MQW) structure in which quantum well layers and quantum barrier layers are alternately stacked on each other. For example, the quantum well layer and the quantum barrier layer may include different compositions of InₓAl_{y}Ga_{1-x-y}N (0≤x≤1, 0≤y≤1, and 0≤x+y≤1), respectively. In some examples, the quantum well layer may include a composition of InₓGa₁₋ₓN(0<x≤1), while the quantum barrier layer may include GaN or AlGaN. The active layer 333 is not limited to the MQW structure, and may have a single quantum well (SQW) structure.

As shown in FIGS. 1 to 3, an encapsulation layer 50 is located on a side of the planarization layer PLN away from the base substrate SUB. The encapsulation layer 50 has a plurality of first receiving parts in one-to-one correspondence with the light-emitting chips 30. The first electrode 31 and the light-emitting body layer 33 of each light-emitting chip 30 are located in the corresponding first receiving part.

A surface of the encapsulation layer 50 away from the base substrate SUB may be flush or substantially flush with a surface of the light-emitting body layer 33 away from the base substrate SUB.

As shown in FIGS. 1 to 3, the light-emitting chip 30 further includes a second electrode 32 on a side of the light-emitting body layer 33 away from the base substrate SUB. The first voltage line 20 further includes a fourth conductive layer 24. The fourth conductive layer 24 and the second electrode 32 of the light-emitting chip 30 are disposed in the same layer, and are both located on a side of the encapsulation layer 50 away from the base substrate SUB. The fourth conductive layer 24 is electrically connected to the second conductive layer 22 through a second via V2 running through the encapsulation layer 50. The second electrode 32 and the fourth conductive layer 24 may be each made of a transparent conductive material such as indium tin oxide (ITO), and each have a thicknesses between 50 nm and 500 nm.

In some embodiments, as shown in FIG. 2, the second electrodes 32 of the plurality of light-emitting chips 30 and the fourth conductive layer 24 may be connected into an integral structure, thereby simplifying the structure and the manufacturing process of the display substrate.

In some embodiments, one or more first voltage lines 20 may be provided. The first voltage line 20 may be located in a display region. For example, the display region of the display substrate includes a plurality of pixel regions each provided with a light-emitting chip 30, and the first voltage line 20 is disposed in a spacing region between two adjacent rows of pixel regions, or in a spacing region between two adjacent columns of pixel regions. Apparently, in other embodiments, the first voltage line 20 may be disposed in a peripheral region around the display region, and the second electrodes 32 of the plurality of light-emitting chips 30 are connected to form a second electrode layer and extend to the peripheral region, so as to be electrically connected to the fourth conductive layer 24 of the first voltage line 20.

As shown in FIG. 3, a light-shielding layer 60 is disposed on a side of the encapsulation layer 50 away from the base substrate SUB, and the light-shielding layer 60 has a plurality of second receiving parts, each of which exposes at least partially the second electrode 32 of one of the light-emitting chips 30. A plurality of light-outgoing parts 70 are disposed on a side of the plurality of light-emitting chips 30 away from the base substrate SUB, and received into the second receiving parts in one-to-one correspondence. The light-shielding layer 60 is configured to prevent light leakage between adjacent light-emitting chips 30, and in one example, the light-shielding layer 60 may have a thickness between 2 μm and 7 μm.

Each light-emitting chip 30 is configured to emit first color light. The plurality of light-outgoing parts 70 include: a plurality of first light-outgoing parts 71, a plurality of second light-outgoing parts 72, and a plurality of third light-outgoing parts 73. For example, the plurality of light-outgoing parts 70 may be divided into a plurality of repetitive units each including one first light-outgoing part 71, one second light-outgoing part 72, and one third light-outgoing part 73. The first light-outgoing part 71 transmits the first color light emitted by the light-emitting chip 30; the second light-outgoing part 72 is configured to convert the first color light into second color light; and the third light-outgoing part 73 is configured to convert the first color light into third color light. For example, the first color light emitted by the light-emitting chip 30 is blue light; the second color light is red light, and the third color light is green light, so that full-color display is realized.

The first light-outgoing part 71 may include a transparent substrate, and may further include light scattering particles doped in the transparent substrate. The second light-outgoing part 72 and the third light-outgoing part 73 may each include a quantum dot material.

Each light-outgoing part 70 may have a thickness between 1 μm and 5 μm, such as 1 μm, 2 μm, or 3 μm, or 4 μm, or 5 μm.

As shown in FIG. 3, the display substrate further includes a plurality of color filter blocks 80 in one-to-one correspondence with the light-outgoing parts 70. Each color filter block 80 is disposed on a side of the corresponding light-outgoing part 70 away from the base substrate SUB, and has a color the same as the light emitted from the corresponding light-outgoing part 70. By providing the color filter blocks 80, the light-emitting wavelength of the quantum dot material can be converged, and the color gamut of the display substrate can be improved. In addition, the first color light in the external environment can be prevented from directly exciting the quantum dot material to influence the display image.

Each color filter block 80 may have a thickness between 1 μm and 2 μm, for example, 1 μm, 1.5 μm, or 2 μm.

In some embodiments, as shown in FIG. 3, the display substrate may further include a protective layer 90 covering the plurality of color filter blocks 80 and the light-shielding layer 60. The protective layer 90 may include an organic film layer and/or an inorganic film layer.

An embodiment of the present disclosure further provides a method for manufacturing a display substrate as described above, which includes the following steps S10 to S50.

At step S10, forming a driver circuit layer on a base substrate.

At step S20, forming a first bonding layer on a side of the driver circuit layer away from the base substrate.

At step S30, providing an epitaxial wafer including a second bonding layer and an epitaxial layer arranged in a stack.

At step S40, transferring the epitaxial wafer to a side of the first bonding layer away from the base substrate, and bonding the first bonding layer to the second bonding layer.

At step S50, etching the epitaxial layer to form a first pattern; etching the second bonding layer to form a second pattern; and etching the first bonding layer to form a third pattern.

The first pattern includes light-emitting body layers of a plurality of light-emitting chips, the second pattern includes first electrodes of the plurality of light-emitting chips and a second conductive layer of a first voltage line, and the third pattern includes a plurality of transfer electrodes, and a first conductive layer of the first voltage line. The transfer electrodes are electrically connected to the driver circuit layer.

In the embodiment of the present disclosure, there is no need to transfer or bond a large number of light-emitting chips through mass transfer and mass bonding processes, as along as the whole epitaxial wafer is transferred, bonded and patterned, thereby reducing the process difficulty. Moreover, the price of a single epitaxial wafer is much lower than a large number of light-emitting chips, thereby reducing the production cost of the display substrate.

In an embodiment of the present disclosure, the base substrate may be a rigid or flexible substrate. The light-emitting chip may be a top-emission structure or a bottom-emission structure. FIGS. 4 to 18 are schematic diagrams illustrating a manufacturing process of a display substrate according to some embodiments of the present disclosure. The manufacturing method according to the embodiments of the present disclosure will be described in detail below with reference to the drawings taking the case where the base substrate SUB is a flexible substrate and the light-emitting chip 30 is a top-emission structure as an example. The method for manufacturing a display substrate includes the following steps S10 to S120.

At step S10, forming a driver circuit layer on a base substrate SUB. Specifically, this step includes steps S11 and S12.

At step S11, as shown in FIG. 4, forming a base substrate SUB of a flexible material on a carrier substrate SUB0, where the carrier substrate SUB0 may be a glass substrate or a hard substrate made of other materials. The base substrate SUB may be made of polyimide, for example, and have a thickness between 3 μm and 20 μm.

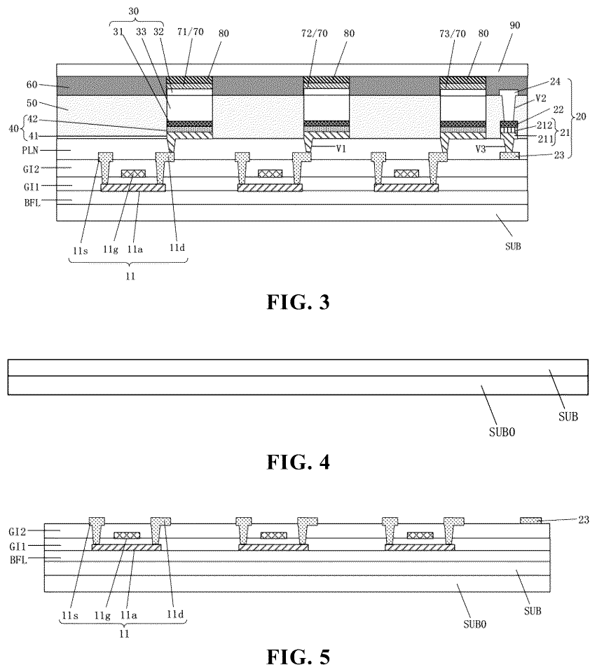

At step S12, as shown in FIG. 5, forming a plurality of thin film transistors 11 on the base substrate SUB. Specifically, this step S12 includes: firstly forming a buffer layer; then forming active layers 11a of the plurality of thin film transistors 11; then forming a first gate insulator layer; then forming gates 11g of the plurality of thin film transistors 11; then forming a second gate insulator layer; and finally forming sources 11s and drains 11d of the plurality of thin film transistors 11.

A third conductive layer 23 of the first voltage line 20 is formed while forming the sources 11s and drains 11d of the plurality of thin film transistors 11. In other words, a source-drain metal layer is formed and patterned, to form a pattern including the sources 11s and drains 11d of the plurality of thin film transistors 11 and the third conductive layer 23.

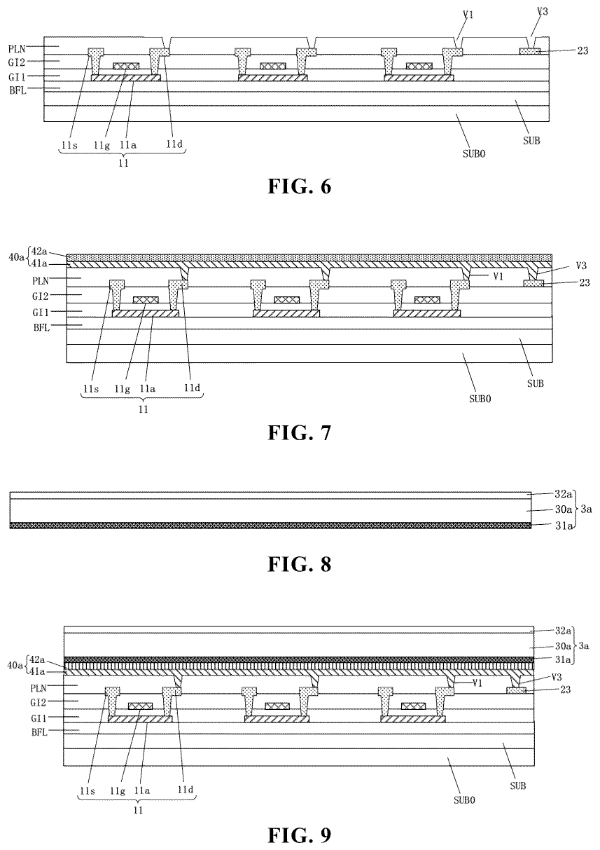

At step S15, as shown in FIG. 6, forming a planarization layer PLN on a side of the driver circuit layer away from the base substrate SUB; and forming a plurality of first and third vias V1 and V3 in the planarization layer PLN.

At step S20, as shown in FIG. 7, forming a first bonding layer 40a on a side of the driver circuit layer away from the base substrate SUB. The first bonding layer 40a is electrically connected to the driver circuit layer through the respective first vias V1.

In one example, the first bonding layer 40a includes a reflective material layer 41a and a bonding material layer 42a sequentially arranged in a direction away from the base substrate SUB. The reflective material layer 41a may be a material layer of Ag, Al, Mo, Ti, Cr, or the like, and may have a thickness between 10 nm and 200 nm; while the bonding material layer 42a is made of a material including the first material, and may have a thickness between 100 nm and 2 μm.

At step S30, as shown in FIG. 8, providing an epitaxial wafer 3a including a second bonding layer 31a and an epitaxial layer 30a arranged in a stack.

In one example, the epitaxial wafer 3a may further include a base 32a, the second bonding layer 31a is located on a side of the epitaxial layer 30a away from the base 32a, and the base 32a may be made of sapphire, Si, SiC, or the like, while the second bonding layer 31a may be made of a material including the above second material. In the embodiments of the present disclosure, the base 32a being a sapphire base 32a is taken as an example for illustration.

At step S40, as shown in FIG. 9, transferring the epitaxial wafer 3a to a side of the first bonding layer 40a away from the base substrate SUB, and bonding the first bonding layer 40a to the second bonding layer 31a.

In one example, the epitaxial wafer 3a is transferred to a side of the first bonding layer 40a away from the base substrate SUB, and integrated with the first bonding layer 40a by thermal pressing, in which process the first bonding layer 40a and the second bonding layer 31a are subjected to metal bonding to implement ohmic conduction.

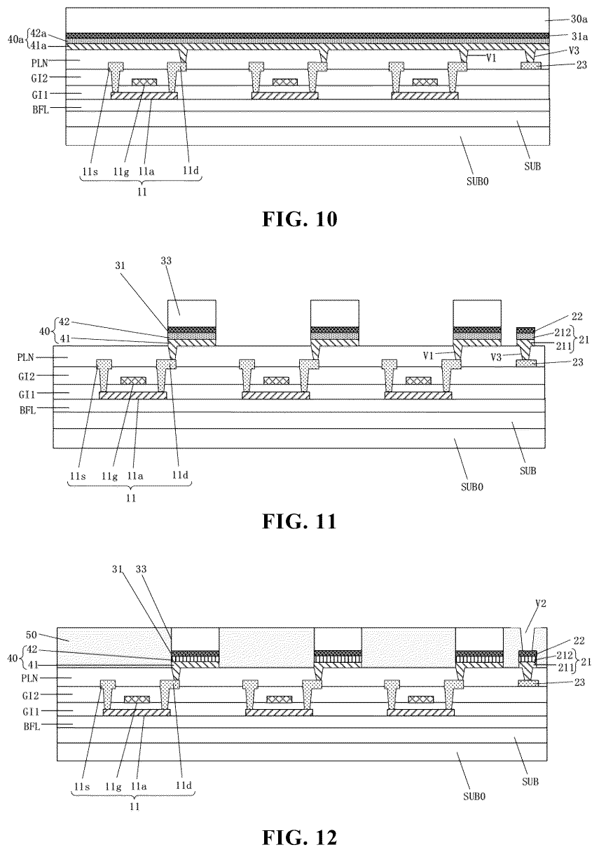

At step S41, as shown in FIG. 10, peeling off the base 32a by laser dissociation.

At step S50, etching the epitaxial layer 30a to form a first pattern; etching the second bonding layer 31a to form a second pattern; and etching the first bonding layer 40a to form a third pattern.

The step S50 includes steps S51 to S52.

At step S51, as shown in FIG. 11, etching the epitaxial layer 30a by a photolithographic patterning process to form a first pattern. The first pattern includes light-emitting body layers 33 of a plurality of light-emitting chips 30.

At step S52, synchronously etching the second bonding layer 31a and the first bonding layer 40a by the same photolithographic patterning process to form a second pattern and a third pattern.

As shown in FIG. 11, the second pattern includes first electrodes 31 of the plurality of light-emitting chips 30, and a second conductive layer 22 of a first voltage line 20; and the third pattern includes a plurality of transfer electrodes 40, and a first conductive layer 21 of the first voltage line 20. Each transfer electrodes 40 is electrically connected to the driver circuit layer through a first via V1. Specifically, the transfer electrode 40 is electrically connected to the drain 11d of the corresponding thin film transistor 11 through the first via V1; and the first conductive layer 21 is electrically connected to the third conductive layer 23 through a third via V3.

Each transfer electrode 40 includes: a reflective layer 41 and a bonding layer 42; and the first conductive layer 21 includes: a first conductive sublayer 211 and a second conductive sublayer 212. The first conductive sublayer 211 and the reflective layer 41 are formed by etching the reflective material layer 41a, and the second conductive sublayer 212 and the bonding layer 42 are formed by etching the bonding material layer 42a.

At step S60, as shown in FIG. 12, forming an encapsulation layer 50 having a plurality of first receiving parts and a plurality of second vias V2. The first electrode 31 and the light-emitting body layer 33 of each light-emitting chip 30 are disposed in one of the first receiving parts.

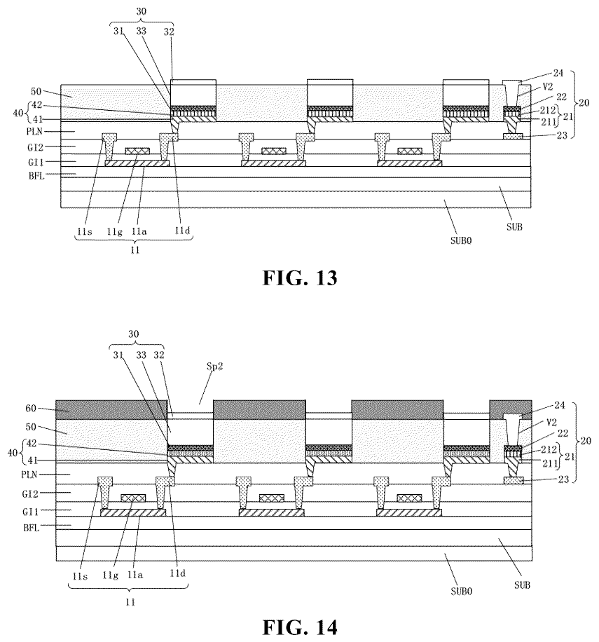

At step S70, as shown in FIG. 13, forming second electrodes 32 of the plurality of light-emitting chips 30 and a plurality of fourth conductive layers 24 of the first voltage line 20 synchronously. The fourth conductive layers 24 are electrically connected to the second conductive layer 22, and the second electrode 32 of each light-emitting chip 30. The second electrode 32 is located on a side of the light-emitting body layer 33 away from the base substrate SUB.

Specifically, a transparent conductive layer may be firstly formed and subjected to a photolithographic patterning process, to form second electrodes 32 of the plurality of light-emitting chips 30 and fourth conductive layers 24 of the plurality of first voltage lines 20.

At step S80, as shown in FIG. 14, forming a light-shielding layer 60 having a plurality of second receiving parts Sp2, where each of the second receiving parts Sp2 exposes at least partially the second electrode 32 of one of the light-emitting chips 30.

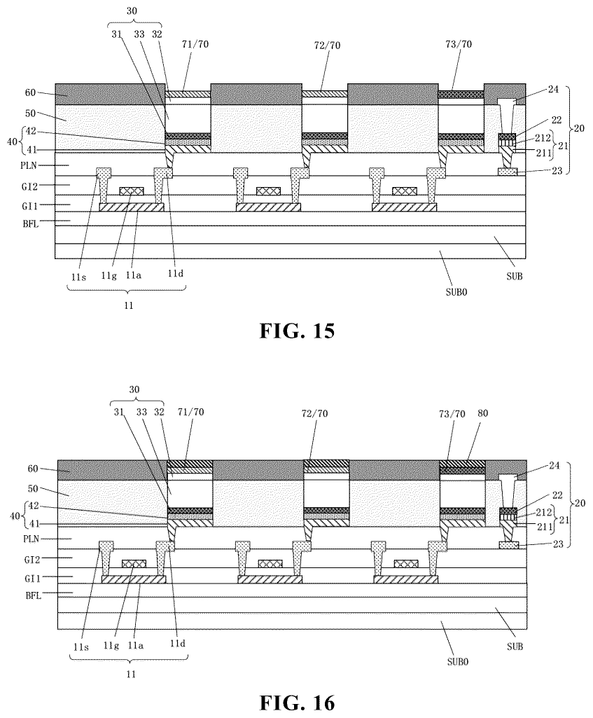

At step S90, as shown in FIG. 15, forming a light-outgoing part 70 in each of the second receiving parts, where the light-outgoing part 70 is located on a side of the second electrode 32 away from the base substrate SUB. Light-outgoing parts 70 in the plurality of second receiving parts include: a first light-outgoing part 71, a second light-outgoing part 72, and a third light-outgoing part 73. The first light-outgoing part 71 transmits the first color light emitted by the light-emitting chip 30; the second light-outgoing part 72 is configured to convert the first color light into second color light; and the third light-outgoing part 73 is configured to convert the first color light into third color light.

Each light-emitting layer has a thickness between 1 μm and 5 μm.

At step S100, as shown in FIG. 16, a color filter block 80 is formed on a side of each light-outgoing part 70 away from the base substrate SUB, and has a color the same as the light emitted from the corresponding light-outgoing part 70.

Each color filter block 80 may have a thickness between 1 μm and 2 μm.

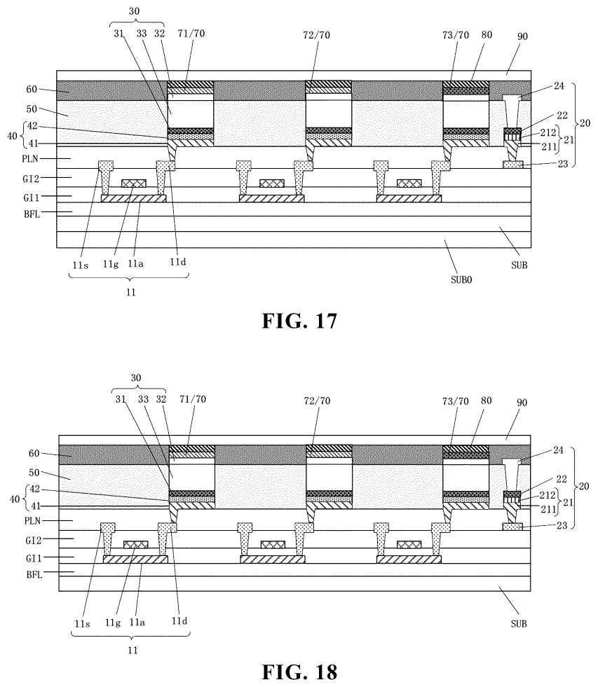

At step S110, as shown in FIG. 17, forming a protective layer 90 covering the plurality of color filter blocks 80 and the light-shielding layer 60. The protective layer 90 may include an organic film layer and/or an inorganic film layer.

At step S120, removing the carrier substrate SUB0 by laser or mechanical separation to obtain the structure shown in FIG. 18, thereby obtaining the flexible display substrate.

An embodiment of the present disclosure further provides a display apparatus, including the display substrate in any of the above embodiments. The display apparatus may be a product or a component with a display function, such as a mobile phone, a television, a display, a tablet, a navigator or the like.

It will be appreciated that the above implementations are merely exemplary implementations for the purpose of illustrating the principle of the present disclosure, and the present disclosure is not limited thereto. It will be apparent to those of ordinary skill in the art that various modifications and variations may be made without departing from the spirit or essence of the present disclosure. Such modifications and variations should also be considered as falling into the protection scope of the present disclosure.

1. A display substrate, comprising:
a base substrate;
a driver circuit layer on the base substrate;
a plurality of transfer electrodes on a side of the driver circuit layer away from the base substrate and electrically connected to the driver circuit layer;
a plurality of light-emitting chips on a side of the plurality of transfer electrodes away from the base substrate, wherein each light-emitting chip comprises a first electrode and a light-emitting body layer sequentially arranged in a direction away from the base substrate, and each first electrode is bonded to one of the transfer electrodes; and
a first voltage line comprising a first conductive layer and a second conductive layer, wherein the first conductive layer is in the same layer as the transfer electrodes, and the second conductive layer is in the same layer as the first electrode; and the first conductive layer is bonded to the second conductive layer.

2. The display substrate according to claim 1, wherein orthographic projections of the first electrode and the transfer electrode connected to the first electrode on the base substrate coincide with each other; and orthographic projections of the first conductive layer and the second conductive layer on the base substrate coincide with each other.

3. The display substrate according to claim 1, wherein the driver circuit layer comprises a plurality of thin film transistors electrically connected to the transfer electrodes;
the first voltage line further comprises: a third conductive layer in the same layer as sources and drains of the thin film transistors, and the first conductive layer is electrically connected to the third conductive layer.

4. The display substrate according to claim 1, wherein each transfer electrode comprises, sequentially in the direction away from the base substrate: a reflective layer and a bonding layer; and
the first conductive layer comprises: a first conductive sublayer and a second conductive sublayer, wherein the first conductive sublayer is in the same layer as the reflective layer, and the second conductive sublayer is in the same layer as the bonding layer.

5. The display substrate according to claim 1, wherein the display substrate further comprises a planarization layer between the driver circuit layer and the plurality of transfer electrodes, and the transfer electrodes are electrically connected to the driver circuit layer through first vias running through the planarization layer.

6. The display substrate according to claim 1, wherein the light-emitting chip further comprises a second electrode on a side of the light-emitting body layer away from the base substrate; and the first voltage line further comprises a fourth conductive layer electrically connected to the second conductive layer, wherein the fourth conductive layer is in the same layer as, and electrically connected to, the second electrode.

7. The display substrate according to claim 6, wherein the display substrate further comprises:
an encapsulation layer on a side of the driver circuit layer away from the base substrate; and the encapsulation layer has a plurality of first receiving parts, each of which receives the first electrode and the light-emitting body layer of one of the light-emitting chips;
wherein the fourth conductive layer is electrically connected to the second conductive layer through a second via running through the encapsulation layer.

8. The display substrate according to claim 7, wherein each light-emitting chip is configured to emit first color light; and the display substrate further comprises:
a light-shielding layer having a plurality of second receiving parts, each of which exposes at least partially one of the second electrodes;
a plurality of light-outgoing parts, each of which is in one of the second receiving parts and on a side of the second electrode away from the base substrate; wherein the plurality of light-outgoing parts comprise: a plurality of first light-outgoing parts, a plurality of second light-outgoing parts, and a plurality of third light-outgoing parts, wherein the first light-outgoing parts transmit the first color light emitted by the light-emitting chips; the second light-outgoing parts are configured to convert the first color light into second color light; and the third light-outgoing parts are configured to convert the first color light into third color light; and
a plurality of color filter blocks, each of which is on a side of one of the light-outgoing parts away from the base substrate and has a color the same as the light emitted from a corresponding light-outgoing part.

9. The display substrate according to claim 1, wherein the light-emitting chips are mini-LED light-emitting chips or Micro-LED light-emitting chips.

10. A method for manufacturing a display substrate, comprising:
forming a driver circuit layer on a base substrate;
forming a first bonding layer on a side of the driver circuit layer away from the base substrate;
providing an epitaxial wafer comprising a second bonding layer and an epitaxial layer in a stack;
transferring the epitaxial wafer to a side of the first bonding layer away from the base substrate, and bonding the first bonding layer to the second bonding layer;
etching the epitaxial layer to form a first pattern; etching the second bonding layer to form a second pattern; and etching the first bonding layer to form a third pattern;
wherein the first pattern comprises light-emitting body layers of a plurality of light-emitting chips, the second pattern comprises first electrodes of the plurality of light-emitting chips and a second conductive layer of a first voltage line, and the third pattern comprises a plurality of transfer electrodes, and a first conductive layer of the first voltage line; and the transfer electrodes are electrically connected to the driver circuit layer.

11. The method according to claim 10, wherein etching the second bonding layer and etching the first bonding layer are performed in a same patterning process.

12. The method according to claim 10, wherein forming the driver circuit layer on the base substrate comprises: forming a plurality of thin film transistors on the base substrate, wherein the transfer electrodes are electrically connected to the thin film transistors;
wherein a third conductive layer of the first voltage line is formed while forming sources and drains of the plurality of thin film transistors; and the first conductive layer is electrically connected to the third conductive layer.

13. The method according to claim 10, wherein the first bonding layer comprises a reflective material layer and a bonding material layer sequentially arranged in a direction away from the base substrate;
each transfer electrode comprises: a reflective layer and a bonding layer; and the first conductive layer comprises: a first conductive sublayer and a second conductive sublayer;
wherein the first conductive sublayer and the reflective layer are formed by etching the reflective material layer, and the second conductive sublayer and the bonding layer are formed by etching the bonding material layer.

14. The method according to claim 10, wherein before forming the first bonding layer, the method further comprises:
forming a planarization layer on a side of the driver circuit layer away from the base substrate; and
forming first vias in the planarization layer at positions corresponding to the transfer electrodes;
wherein the transfer electrodes are electrically connected to the driver circuit layer through the first vias, respectively.

15. The method according to claim 10, wherein the method further comprises:
forming second electrodes of the plurality of light-emitting chips and a plurality of fourth conductive layers of the first voltage line synchronously;
wherein the fourth conductive layers are electrically connected to the second conductive layer and the second electrode, and the second electrode is on a side of the light-emitting body layer away from the base substrate.

16. The method according to claim 15, wherein before forming the second electrodes of the plurality of light-emitting chips synchronously, the method further comprises:
forming an encapsulation layer having a plurality of first receiving parts and a plurality of second vias;
wherein the first electrode and the light-emitting body layer of each light-emitting chip are in one of the first receiving parts, and the fourth conductive layers are electrically connected to the second conductive layer through the second vias.

17. The method according to claim 16, wherein each light-emitting chip is configured to emit first color light; and the method further comprises:
forming a light-shielding layer having a plurality of second receiving parts;
forming a light-outgoing part in each of the second receiving parts, wherein the light-outgoing part is on a side of the second electrodes away from the base substrate;
light-outgoing parts in the plurality of second receiving parts comprise: a first light-outgoing part, a second light-outgoing part, and a third light-outgoing part, wherein the first light-outgoing part transmits the first color light emitted by the light-emitting chips, the second light-outgoing part is configured to convert the first color light into second color light; and the third light-outgoing part is configured to convert the first color light into third color light; and
forming a color filter block on a side of each light-outgoing part away from the base substrate, wherein the color filter block has a color the same as the light emitted from a corresponding light-outgoing part.

18. A display apparatus, comprising: the display substrate according to claim 1.

19. The display substrate according to claim 2, wherein the driver circuit layer comprises a plurality of thin film transistors electrically connected to the transfer electrodes;
the first voltage line further comprises: a third conductive layer in the same layer as sources and drains of the thin film transistors, and the first conductive layer is electrically connected to the third conductive layer.

20. The display substrate according to claim 2, wherein each transfer electrode comprises, sequentially in the direction away from the base substrate: a reflective layer and a bonding layer; and
the first conductive layer comprises: a first conductive sublayer and a second conductive sublayer, wherein the first conductive sublayer is in the same layer as the reflective layer, and the second conductive sublayer is in the same layer as the bonding layer.
